(19) United States
(12) Patent Application Publication
(10) Pub. No.: US 2024/0194673 A1
(43) Pub. Date: Jun. 13, 2024

(54) INTEGRATION OF FINFET AND GATE-ALL-AROUND DEVICES

(71) Applicant: Intel Corporation, Santa Clara, CA (US)

(72) Inventors: Hwichan Jun, Portland, OR (US); Guillaume Bouche, Hillsboro, OR (US)

(73) Assignee: Intel Corporation, Santa Clara, CA (US)

(21) Appl. No.: 18/077,394

(22) Filed: Dec. 8, 2022

(51) Int. Cl. H01L 27/088; H01L 29/06; H01L 29/08; H01L 29/423; H01L 29/78

(52) U.S. Cl. CPC H01L 27/0886; H01L 29/0673; H01L 29/0847; H01L 29/42356; H01L 29/42392; H01L 29/785

(57) ABSTRACT

Techniques to form semiconductor devices that include both finFET and gate-all-around (GAA) devices on same substrate. The finFET and GAA devices may have different gate oxide thicknesses and/or shallow trench isolation (STI) thicknesses, along with coplanar channel regions. In an example, a first semiconductor device includes a finFET structure with a first gate structure around or otherwise on a semiconductor fin while a second semiconductor device includes a GAA structure with a second gate structure around or otherwise on a plurality of semiconductor bodies (e.g., nanoribbons). The first gate structure includes a first gate dielectric and a first gate electrode (e.g., conductive material such as workfunction material and/or gate fill metal) and the second gate structure includes a second gate dielectric and a second gate electrode. The first gate dielectric includes a first gate oxide layer that is thicker than a second gate oxide layer of the second gate dielectric.

### FIELD OF THE DISCLOSURE

The present disclosure relates to integrated circuits, and more particularly, to non-planar semiconductor devices.

### BACKGROUND

As integrated circuits continue to scale downward in size, a number of challenges arise. For instance, reducing the size of memory and logic cells is becoming increasingly more difficult, as is reducing device spacing at the device layer. Different device geometries have been contemplated to maximize the use of limited chip footprint. Some geometries may be better suited for certain tasks compared to other geometries. Accordingly, there remain a number of non-trivial challenges with respect to forming such semiconductor devices.

### BRIEF DESCRIPTION OF THE DRAWINGS

FIGS. 1A and 1B are cross-sectional and plan views, respectively, of some semiconductor devices that illustrate a finFET device and a gate-all-around (GAA) device having different gate oxide thicknesses, in accordance with an embodiment of the present disclosure.

FIGS. 2A-2K are cross-sectional views that illustrate various stages in an example process for forming semiconductor devices that have a finFET device and a GAA device with different gate oxide thicknesses, in accordance with some embodiments of the present disclosure.

FIG. 3 illustrates a cross-sectional view of a chip package containing one or more semiconductor dies, in accordance with some embodiments of the present disclosure.

FIG. 4 is a flowchart of a fabrication process for semiconductor devices having a finFET device and a GAA device with different gate oxide thicknesses, in accordance with an embodiment of the present disclosure.

FIG. 5 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form semiconductor devices that include both finFET and gate-all-around (GAA) devices on the same substrate. In some examples, the finFET and GAA devices have different gate oxide thicknesses. In some such examples, shallow trench isolation (STI) adjacent a subfin region under a given GAA device extends deeper into the underlying substrate or is otherwise thicker than STI adjacent a subfin region under a given finFET device. The techniques can be used in any number of integrated circuit applications. In an example, a first semiconductor device includes a finFET structure with a first gate structure around or otherwise on a semiconductor fin while a second semiconductor device includes a GAA structure with a second gate structure around or otherwise on a plurality of semiconductor nanoribbons. The first gate structure includes a first gate dielectric and a first gate electrode (e.g., conductive material such as workfunction material and/or gate fill metal) and the second gate structure includes a second gate dielectric and a second gate electrode. According to some embodiments, the first gate dielectric includes a first gate oxide layer that is thicker than a second gate oxide layer of the second gate dielectric. The finFET device with the thicker gate oxide layer may be used for handling higher current (such as from power rails) compared to the GAA device with the thinner gate oxide due to limited space. Numerous variations and embodiments will be apparent in light of this disclosure.

### General Overview

As previously noted above, there remain a number of non-trivial challenges with respect to integrated circuit fabrication. In more detail, as devices become smaller and more densely packed, many structures become more challenging to fabricate as critical dimensions (CD) of the structures push the limits of current fabrication technology. Integrating different device geometries is especially challenging due to the batch fabrication process across the entire surface of a wafer. However, some device geometries may be better suited for certain tasks than others. For example, transistors that have to handle higher currents (e.g., from I/O ports or power rails on a chip) usually require thicker gate oxides to function properly. But thick gate oxide layers are challenging to include with GAA devices due to the limited spacing between nanoribbons. FinFET devices are better suited for having thicker gate oxide layers, but cannot pass as much current through it as a GAA device.

Thus, and in accordance with an embodiment of the present disclosure, techniques are provided herein to form both finFET devices and GAA devices on the same substrate and with different gate oxide thicknesses. In some embodiments, a well is formed in the substrate and is filled with alternating semiconductor layers to form one or more GAA devices. One or more finFET devices may be formed from the substrate outside of the well. In some embodiments, a single etching process may be used for form fins of alternating semiconductor layers in the well and fins of substrate semiconductor material outside of the well. According to some embodiments, the substrate may be etched deeper around the GAA devices compared to around the finFET devices due to the speed of the etch through the alternating semiconductor layers within the well. According to some embodiments, a top surface of the finFET devices may be substantially coplanar (e.g., within 1 nm or within 2 nm of one another) with a top surface of a topmost nanoribbon of the GAA devices. In some such examples, the top surfaces refer to the uppermost channel region surfaces (e.g., top surface of fin, and top surface of uppermost nanoribbon). A thicker gate oxide may be formed around the finFET devices compared to the gate oxide formed around the GAA devices. In this way, GAA devices may still be used for their high-current throughput and faster switching speeds while finFET devices can be used for power and I/O applications on the same chip.

According to an embodiment, an integrated circuit includes a first semiconductor device having a semiconductor fin extending in a first direction from a first source region to a first drain region, and a first gate structure extending in a second direction over the semiconductor fin. The integrated circuit also includes a second semiconductor device having a plurality of semiconductor bodies (e.g., nanoribbons) extending in the first direction from a second source region to a second drain region, and a second gate structure extending in the second direction over the plurality of semiconductor bodies. The first gate structure has a first gate dielectric structure and a first gate electrode on the first gate dielectric structure, and the second gate structure has a second gate dielectric structure and a second gate electrode on the second gate dielectric structure. The first gate dielectric structure includes a first gate oxide layer and the second gate dielectric structure includes a second gate oxide layer. The first gate oxide layer is at least 2 nm thicker than the second gate oxide layer.

According to an embodiment, an integrated circuit includes a substrate, a first semiconductor device having a semiconductor fin that is part of the substrate and extending in a first direction from a first source region to a first drain region, and a first gate structure extending in a second direction over the semiconductor fin, and a second semiconductor device having a plurality of semiconductor bodies (e.g., nanoribbons) over the substrate and extending in the first direction from a second source region to a second drain region, and a second gate structure extending in the second direction over the plurality of semiconductor bodies. The first gate structure has a first gate dielectric structure and a first gate electrode on the first gate dielectric structure, and the second gate structure has a second gate dielectric structure and a second gate electrode on the second gate dielectric structure. The substrate includes a first subfin region under the semiconductor fin and having a first dielectric layer adjacent to the first subfin region, and a second subfin region under the plurality of semiconductor bodies and having a second dielectric layer adjacent to the second subfin region. The second dielectric layer has a greater thickness than the first dielectric layer.

According to another embodiment, a method of forming an integrated circuit includes forming a recess in a substrate; forming alternating first and second semiconductor layers within the recess; forming a first fin comprising first semiconductor material, the first fin extending above the substrate and extending in a first direction; forming a second fin comprising the first and second semiconductor layers, the second fin extending above the substrate and extending in the first direction; forming a first gate dielectric layer having a first thickness over the first fin and the second fin; forming a masking layer over the first fin and removing the first gate dielectric layer from the second fin; removing the second semiconductor layers from the second fin to yield semiconductor nanoribbons from the first semiconductor layers; and forming a second gate dielectric layer having a second thickness around the semiconductor nanoribbons, wherein the second thickness of the second gate dielectric layer is less than the first thickness of the first gate dielectric layer.

The techniques can be used with any type of non-planar transistors, including finFETs (sometimes called tri-gate transistors), nanowire and nanoribbon transistors (sometimes called gate-all-around transistors), or forksheet transistors, to name a few examples. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of finFET and GAA devices integrated together on the same substrate. Furthermore, the gate oxide thickness may be noticeably greater on the finFET devices compared to the GAA devices. For example, the gate dielectric thickness on the finFET devices may be at least 2 nm thicker than the gate dielectric thickness on the GAA devices. Also, or alternatively, shallow trench isolation (STI) adjacent a subfin region under a given GAA device extends deeper into the underlying substrate or is otherwise thicker than STI adjacent a subfin region under a given finFET device. Also, the top channel level for the finFET devices may be substantially coplanar with the top channel level of the GAA devices. Numerous configurations and variations will be apparent in light of this disclosure.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element (s) or feature (s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the materials has an element that is not in the other material.

### Architecture

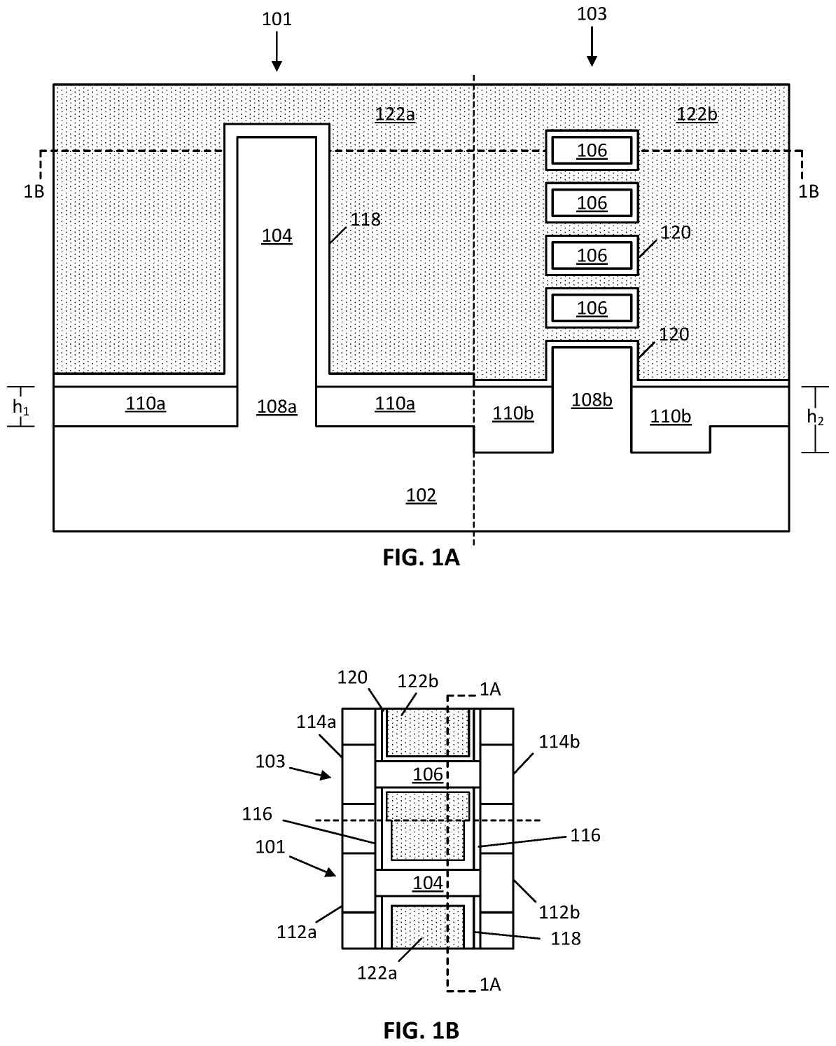

FIG. 1A is a cross-sectional view taken across two example semiconductor devices 101 and 103 populated on a given die, according to an embodiment of the present disclosure. FIG. 1B is a top-down cross-section view of the semiconductor devices 101 and 103 taken across the dashed line 1B-1B depicted in FIG. 1A, and FIG. 1A illustrates the cross-section taken across the dashed line 1A-1A depicted in FIG. 1B. According to some embodiments, semiconductor device 101 is a finFET device and semiconductor device 103 is a GAA device, although other transistor topologies and types could also benefit from the techniques and structures provided herein. Semiconductor devices 101 and 103 represent a portion of an integrated circuit that may contain any number of similar semiconductor devices.

According to some embodiments, semiconductor device 101 may represent any number of similar finFET devices while semiconductor device 103 may represent any number of similar GAA devices. Semiconductor devices 101 and 103 are shown side-by-side in the figure for the sake of description, but the devices may be separately located anywhere on a same substrate 102. The vertical dashed line in FIG. 1A is used to indicate that semiconductor devices 101 and 103 do not need to be directly adjacent to one another and could be located at any position away from one another on substrate 102.

Any number of semiconductor devices can be formed on substrate 102, but two are used here as an example. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 102 can be a semiconductor-on-insulator substrate having a desired semiconductor layer over a buried insulator layer (e.g., silicon over silicon dioxide). Alternatively, substrate 102 can be a multilayer substrate or superlattice suitable for forming nanowires or nanoribbons (e.g., alternating layers of silicon and SiGe, or alternating layers indium gallium arsenide and indium phosphide). Any number of substrates can be used. In some example embodiments, a lower portion of (or all of) substrate 102 is removed and replaced with one or more backside interconnect layers to form backside signal and power routing.

Semiconductor device 101 includes a fin 104 of semiconductor material while semiconductor device 103 includes one or more nanoribbons 106. Both fin 104 and nanoribbons 106 extend parallel to one another along a direction between corresponding source drain regions (e.g., a first direction into and out of the page in the cross-section view of FIG. 1A). Fin 104 and nanoribbons 106 are some examples of semiconductor regions or semiconductor bodies that extend between source and drain regions. The term nanoribbon may also encompass other similar shapes such as nanowires or nanosheets. The semiconductor material of fin 104 may be formed from substrate 102 (e.g., native to the substrate). In some embodiments, a fin may be formed that includes alternating layers of material (e.g., alternating layers of silicon and SiGe) that facilitates forming of the illustrated nanoribbons 106 during a gate forming process where one type of the alternating layers is selectively etched away so as to liberate the other type of alternating layers within the channel region, so that a GAA process can then be carried out. The alternating layers can be blanket deposited and then etched into fins or deposited into fin-shaped trenches, according to some examples.

As can further be seen, semiconductor devices 101 and 103 each include a subfin region 108a and a subfin region 108b, respectively. According to some embodiments, subfin regions 108a/108b comprise the same semiconductor material as substrate 102. According to some embodiments, subfin region 108a may be defined by the portion of fin 104 that has a dielectric fill 110a directly adjacent to it. According to some embodiments, subfin region 108b may be defined by the portion of the fin beneath nanoribbons 106 and a part of substrate 102. Another dielectric fill 110b may be adjacent to at least a portion of subfin 108b. Note that a top surface of subfin 108b may extend above a top surface of the adjacent dielectric fill 110b. Dielectric fill 110a/110b provides shallow trench isolation (STI) between any adjacent semiconductor devices, and any adjacent subfin regions of those devices. Dielectric fill 110a/110b can be any suitable dielectric material, such as silicon dioxide, aluminum oxide, or silicon oxycarbonitride. As shown in FIG. 1A, dielectric fill 110a adjacent to subfin region 108a of semiconductor device 101 has a first thickness h₁ and dielectric fill 110b adjacent to at least a portion of subfin region 108b of semiconductor device 103 has a second thickness h₂. According to some embodiments, the process used to simultaneously form the fins for each of semiconductor devices 101 and 103 results in a deeper etch into substrate 102 for semiconductor device 103 compared to semiconductor device 101, leading to a thicker dielectric fill 110b. In some examples, the second thickness h₂ of dielectric fill 110b is at least 2 nm, at least 5 nm, or at least 10 nm thicker than the first thickness h₁ of dielectric fill 110a.

According to some embodiments, fin 104 and nanoribbons 106 extend between corresponding source and drain regions in the first direction to provide active regions for transistors (e.g., the semiconductor regions beneath the gate). The source and drain regions are not shown in the cross-section of FIG. 1A, but are seen in the top-down view of FIG. 1B where fin 104 of semiconductor device 101 extends between a source region 112a and a drain region 112b (similarly, the nanoribbons 106 of semiconductor device 103 extend between a source region 114a and a drain region 114b). FIG. 1B also illustrates spacer structures 116 that extend around the ends of fin 104 and nanoribbons 106 and along sidewalls of the gate structures between spacer structures 116. Spacer structures 116 may include a dielectric material, such as silicon nitride.

According to some embodiments, the source and drain regions are epitaxial regions that are provided using an etch-and-replace process. In other embodiments one or both of the source and drain regions could be, for example, implantation-doped native portions of the semiconductor fins or substrate. Any semiconductor materials suitable for source and drain regions can be used (e.g., group IV and group III-V semiconductor materials). The source and drain regions may include multiple layers such as liners and capping layers to improve contact resistance. In any such cases, the composition and doping of the source and drain regions may be the same or different, depending on the polarity of the transistors. In an example, for instance, one transistor is a p-type MOS (PMOS) transistor, and the other transistor is an n-type MOS (NMOS) transistor. Any number of source and drain configurations and materials can be used.

According to some embodiments, a first gate structure extends over fin 104 of semiconductor device 101 along a second direction across the page while a second gate structure extends over nanoribbons 106 of semiconductor device 103 along the second direction. The second direction may be orthogonal to the first direction. Each gate structure includes a respective gate dielectric and a gate layer (or gate electrode). For example, the first gate structure includes a first gate dielectric having at least a first gate oxide layer 118 and a first gate electrode 122a while second gate structure includes a second gate dielectric having at least a second gate oxide layer 120 and a second gate electrode 122b. Note that the first gate dielectric represents any number of dielectric layers present between fin 104 and first gate electrode 122a and the second gate dielectric represents any number of dielectric layers present between nanoribbons 106 and second gate electrode 122b. The illustrated first gate oxide layer 118 represents one layer of the first gate dielectric and the illustrated second gate oxide layer 120 represents one layer of the second gate dielectric, according to some embodiments. The first and second gate dielectrics may also be present on the surfaces of other structures within the gate trenches. In some embodiments, the first and second gate dielectrics include the corresponding first gate oxide layer 118 and second gate oxide layer 120, and each include a layer of high-K dielectric material (e.g., hafnium oxide) on the first gate oxide layer 118 and second gate oxide layer 120.

Gate electrode 122a/122b may represent any number of conductive layers, such as any metal, metal alloy, or doped polysilicon layers. In some embodiments, gate electrode 122a/122b includes one or more workfunction metals around fin 104 and/or nanoribbons 106. In some embodiments, one of semiconductor devices 101 and 103 is a p-channel device that include a workfunction metal having titanium and the other semiconductor device is an n-channel device that includes a workfunction metal having tungsten. Gate electrode 122a/122b may also include a fill metal or other conductive material (e.g., tungsten, ruthenium, molybdenum, copper, aluminum) around the workfunction metals to provide the whole gate electrode structure.

According to some embodiments, first gate oxide layer 118 has a greater thickness compared to second gate oxide layer 120. For example, first gate oxide layer 118 is at least 1 nm, at least 2 nm, or at least 5 nm thicker than second gate oxide layer 120. As noted above, other dielectric layers, such as one or more high-k dielectric layers, may be formed over each of first gate oxide layer 118 and second gate oxide layer 120. In one example, a dielectric layer that includes hafnium oxide may be formed over both first gate oxide layer 118 and second gate oxide layer 120. The hafnium oxide layer may have the same thickness on both first gate oxide layer 118 and second gate oxide layer 120.

### Fabrication Methodology

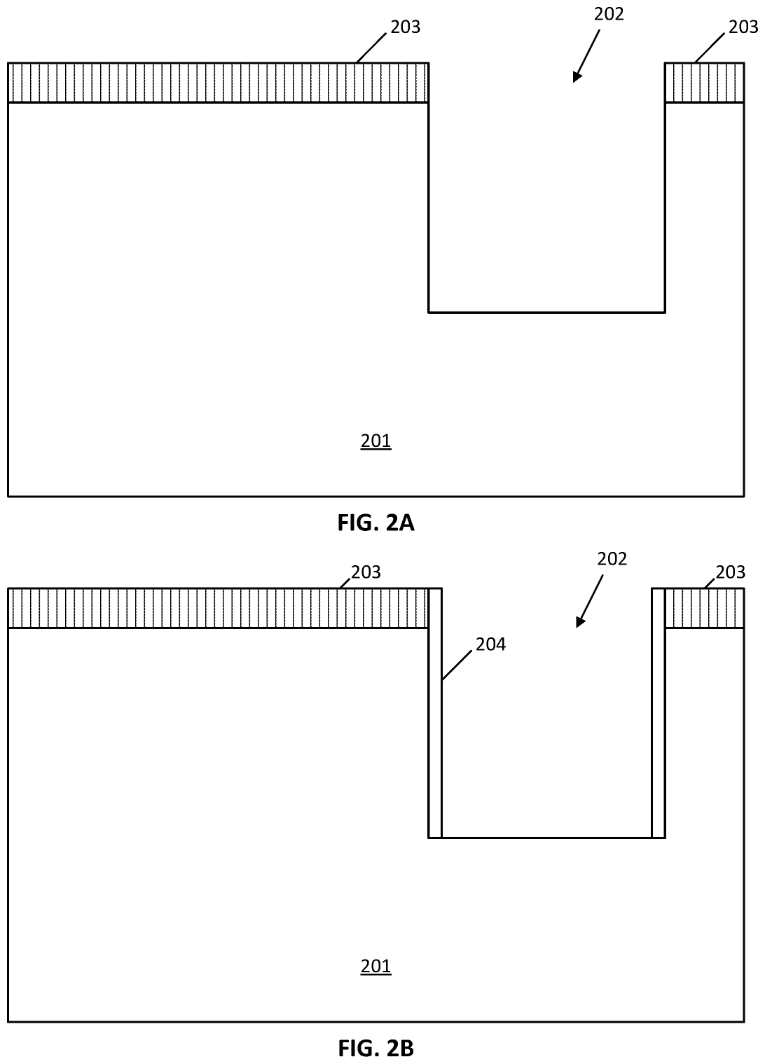

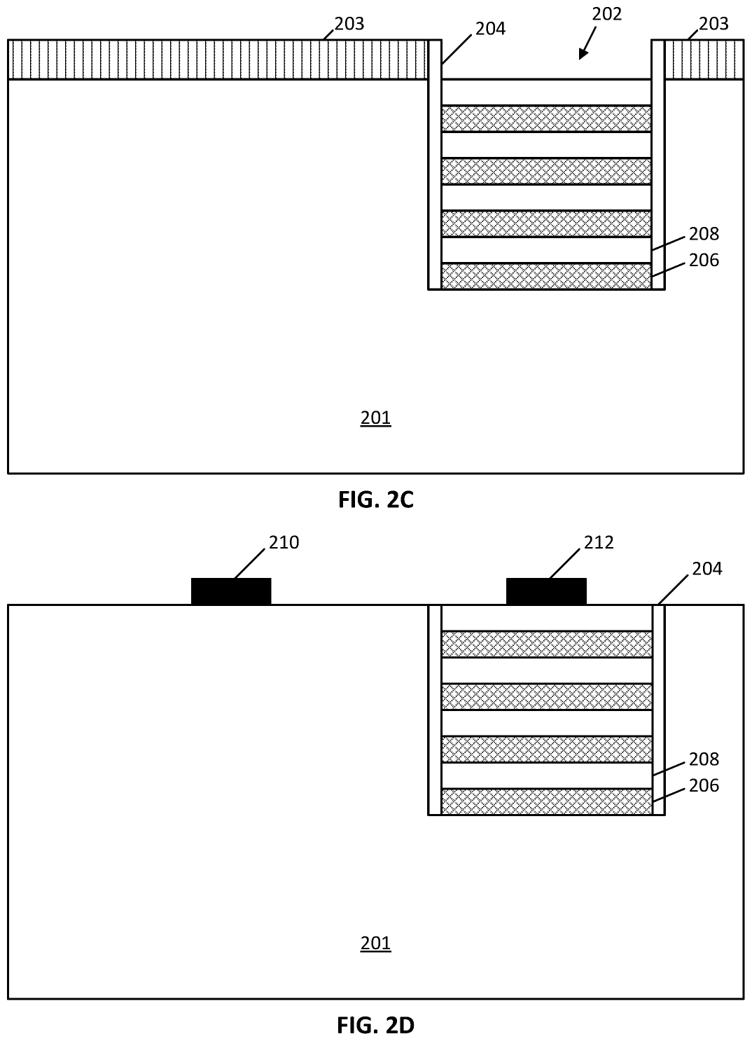

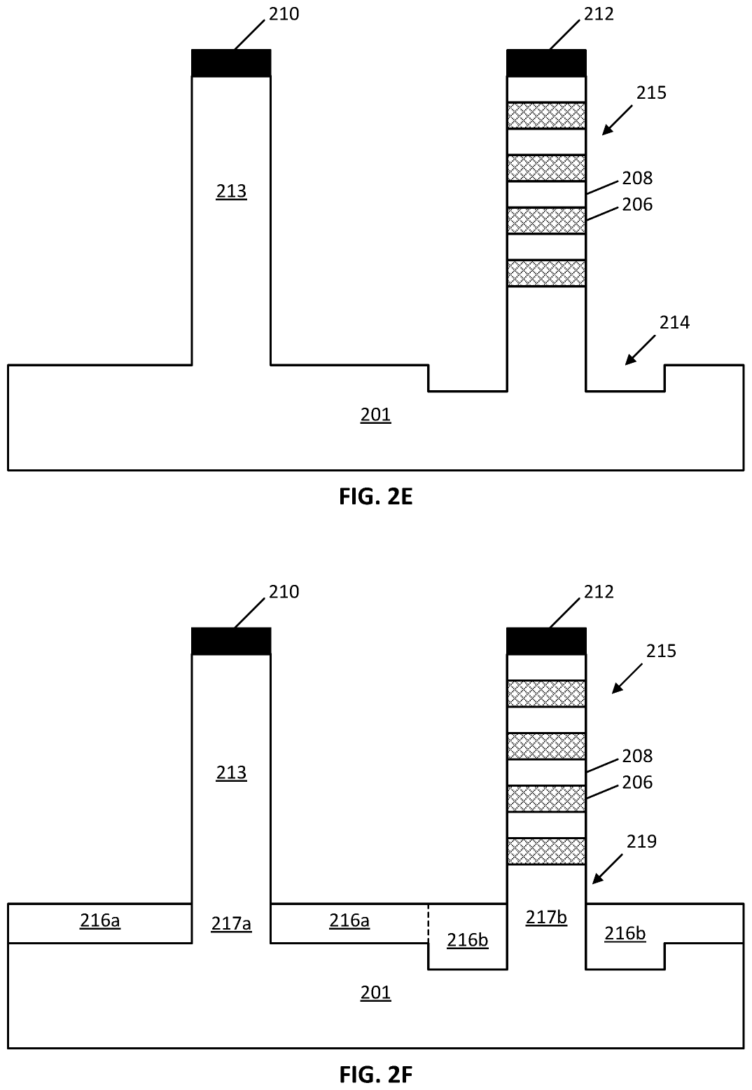

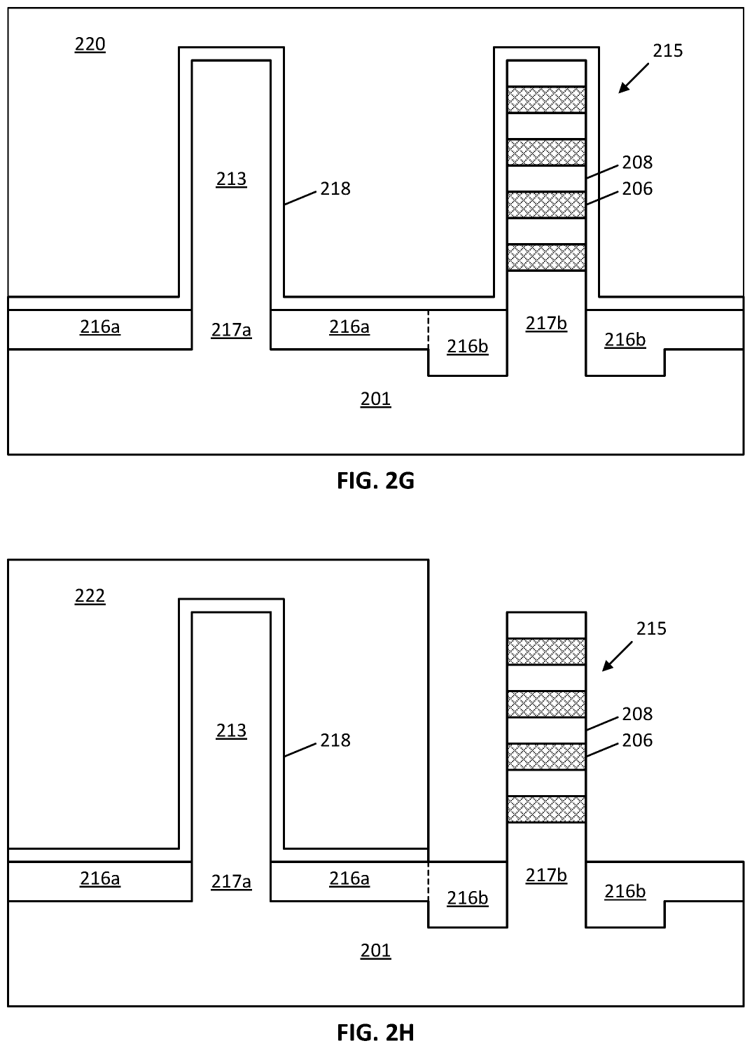

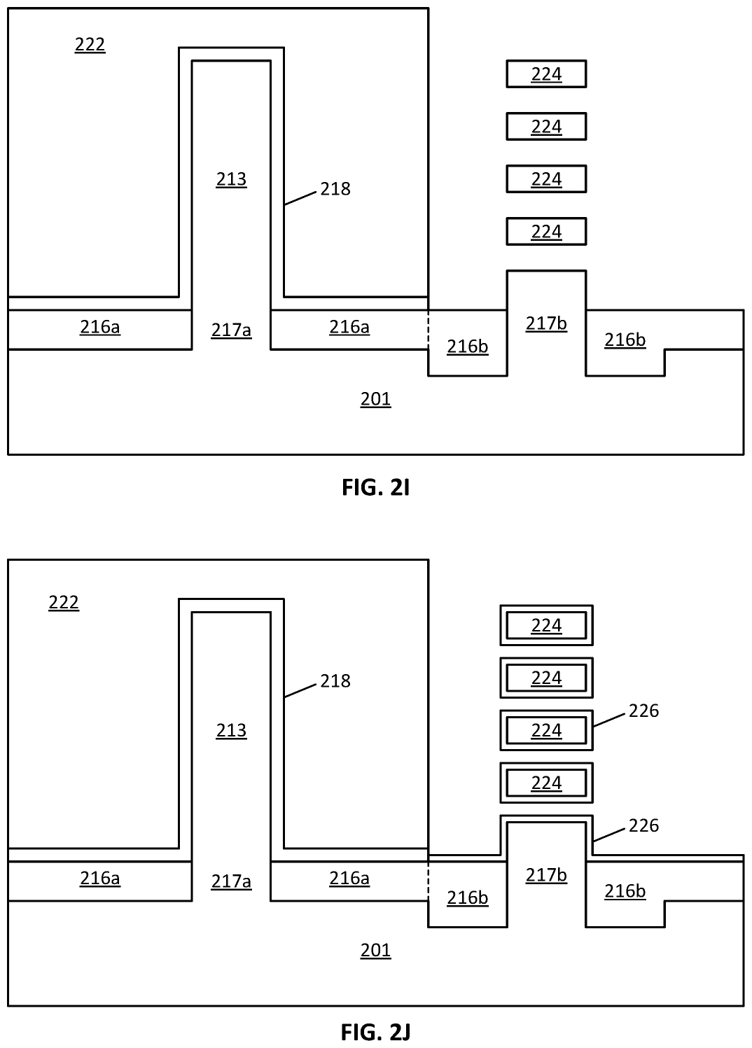

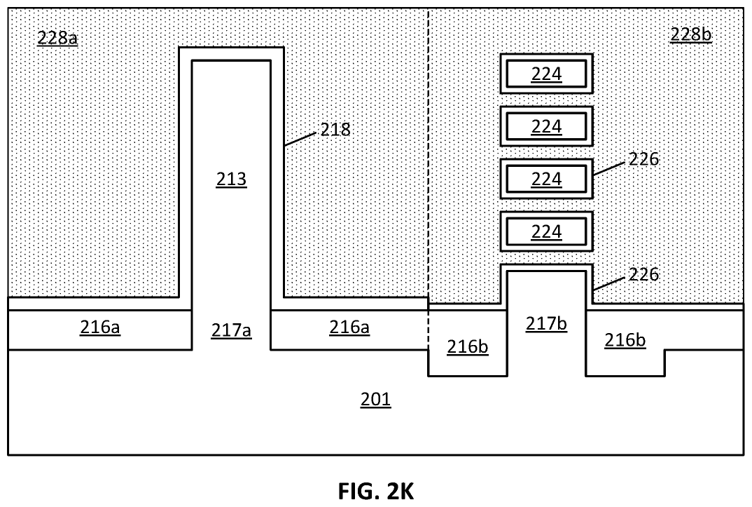

FIGS. 2A-2K include cross-sectional views that collectively illustrate an example process for forming an integrated circuit with semiconductor devices that have a finFET device and a GAA device with different gate oxide thicknesses, in accordance with an embodiment of the present disclosure. Each figure shows an example structure that results from the process flow up to that point in time, so the depicted structure evolves as the process flow continues, culminating in the structure shown in FIG. 2K, which is similar to the structure shown in FIG. 1A. The illustrated integrated circuit structure may be part of a larger integrated circuit that includes other integrated circuitry not depicted. Example materials and process parameters are given, but the present disclosure is not intended to be limited to any specific such materials or parameters, as will be appreciated. Although the fabrication of two semiconductor devices is illustrated in the aforementioned figures, it should be understood that any number of similar devices can be fabricated across the integrated circuit using the same processes discussed herein.

FIG. 2A illustrates a cross-sectional view taken through a substrate 201, in which a well 202 is formed in substrate 201, according to an embodiment of the present disclosure. The description above for substrate 102 applies equally to substrate 201. Well 202 may be formed using an anisotropic etching process, such as reactive ion etching (RIE). A mask structure 203 protects portions of substrate 201 from the etching process. Mask structure 203 may include any suitable hard mask material, such as silicon nitride. Well 202 may have any width to accommodate any number of GAA devices within it as will be described in more detail herein. The depth of well 202 may be selected based on a number of desired nanoribbons within the GAA devices and on a desired thickness and spacing between the nanoribbons.

FIG. 2B depicts the cross-section view of the structure shown in FIG. 2A following the formation of a liner layer 204 within well 202, according to an embodiment of the present disclosure. Liner layer 204 may be deposited using chemical vapor deposition (CVD) or atomic layer deposition (ALD) to at least conformally cover the sidewalls of well 202. An anisotropic etch-back process may then be used to remove planar sections of liner layer 204 and leave it on the sidewalls of well 202. According to some embodiments, liner layer includes a dielectric material, such as silicon nitride or silicon dioxide.

FIG. 2C depicts the cross-section view of the structure shown in FIG. 2B following the formation of a series of material layers within well 202, according to an embodiment of the present disclosure. Alternating material layers may be formed within well 202 including sacrificial layers 206 alternating with semiconductor layers 208. The alternating layers are used to form GAA transistor structures. Any number of alternating semiconductor layers 208 and sacrificial layers 206 may be formed within well 202.

According to some embodiments, sacrificial layers 206 have a different material composition than semiconductor layers 208. In some embodiments, sacrificial layers 206 are silicon germanium (SiGe) while semiconductor layers 208 include a semiconductor material suitable for use as a nanoribbon such as silicon (Si), SiGe, germanium, or III-V materials like indium phosphide (InP) or gallium arsenide (GaAs). In examples where SiGe is used in each of sacrificial layers 206 and in semiconductor layers 208, the germanium concentration is different between sacrificial layers 206 and semiconductor layers 208. For example, sacrificial layers 206 may include a higher germanium content compared to semiconductor layers 208. In some examples, semiconductor layers 208 may be doped with either n-type dopants (to produce a p-channel transistor) or p-type dopants (to produce an n-channel transistor).

While dimensions can vary from one example embodiment to the next, the thickness of each sacrificial layer 206 may be between about 5 nm and about 20 nm. In some embodiments, the thickness of each sacrificial layer 206 is substantially the same (e.g., within 1-2 nm). The thickness of each of semiconductor layers 208 may be about the same as the thickness of each sacrificial layer 206 (e.g., about 5-20 nm). Each of sacrificial layers 206 and semiconductor layers 208 may be deposited using any known or proprietary material deposition technique, such as CVD, plasma-enhanced chemical vapor deposition (PECVD), physical vapor deposition (PVD), or ALD. In other embodiments, each of sacrificial layers 206 and semiconductor layers 208 are epitaxially grown over one another within well 202. The first epitaxially grown layer may be seeded directly from the exposed surface of substrate 201 at the bottom of well 202.

The topmost layer of the alternating material layers within well 202 may be either a semiconductor layer 208 or a sacrificial layer 206. The growth of the topmost layer may extend outside of well 202 and be polished back using, for example, chemical mechanical polishing (CMP). In examples where the topmost layer is a semiconductor layer 208, the resulting GAA device will have a top surface of its topmost nanoribbon be substantially coplanar with a top surface of the resulting fin device. In examples where the topmost layer is a sacrificial layer 206, the resulting GAA device will have a top surface of its topmost nanoribbon that is lower than a top surface of the resulting fin device.

FIG. 2D depicts the cross-section view of the structure shown in FIG. 2C following the formation of cap layers 210 and 212, according to an embodiment of the present disclosure. Mask structure 203 and portions of liner layer 204 on mask structure 203 may be removed using either a wet etching process or by using CMP. Cap layers 210/212 may be any suitable hard mask material such as a carbon hard mask (CHM) or silicon nitride. Cap layers 210/212 are patterned into rows to form corresponding rows of fins from the material beneath cap layers 210/212. The rows of fins extend lengthwise in a first direction (e.g., into and out of the page). According to some embodiments, cap layer 210 is formed over substrate 201 outside of the alternating layer structure and cap layer 212 is formed on the alternating layer structure having sacrificial layers 206 alternating with semiconductor layers 208. As noted above, cap layer 210 may represent any number of similar cap layers formed on substrate 201 and cap layer 212 may represent any number of similar cap layers formed on the alternating layer structure.

FIG. 2E depicts the cross-section view of the structure shown in FIG. 2D following an etching process around cap layers 210/212 to form fins of semiconductor material, according to an embodiment of the present disclosure. For example, an anisotropic etching process using RIE may be performed through substrate 201 around cap layer 210 to form fin 213 and through the alternating layer stack around cap layer 212 to form a fin 215 of alternating semiconductor layers 208 and sacrificial layers 206. According to some embodiments, the RIE process etches deeper into substrate 201 as it passes through the alternating layer stack to form recesses 214. This may occur due to the etch rate being faster through sacrificial layers 206 compared to semiconductor layers 208.

FIG. 2F depicts the cross-section view of the structure shown in FIG. 2E following the formation of dielectric fill 216a/216b around subfin regions 217a/217b of the fins, according to an embodiment of the present disclosure. Dielectric fill 216a/216b may be any suitable dielectric material such as silicon dioxide and may be deposited using CVD, polished, and then etched back to its final respective height. Due to the presence of recesses 214, dielectric fill 216b around at least a portion of subfin region 217b is thicker compared to dielectric fill 216a around subfin region 217a. As noted above, subfin region 217b beneath the alternating layer stack may extend above a top surface of dielectric fill 216b. Accordingly, in some embodiments, dielectric fill 216b is recessed below a top surface of subfin region 217b thus exposing a top portion 219 of subfin region 217b. The vertical dashed line separating dielectric fill 216a from dielectric fill 216b once again indicates that the fins need not be directly adjacent as illustrated and could be located at any distance from one another (with any number of intervening structures). According to some embodiments, dielectric fill 216b may have a thickness that is at least 2 nm, at least 5 nm, or at least 10 nm thicker than dielectric fill 216a.

FIG. 2G depicts the cross-section view of the structure shown in FIG. 2F following the formation of a first gate oxide layer 218 and a sacrificial gate 220 extending across the fins in a second direction different from the first direction, according to some embodiments. First gate oxide layer 218 may be deposited using CVD or ALD to conformally coat both fin 213 and fin 215. First gate oxide layer 218 may be a low-k dielectric material having a dielectric constant between 4 and 6. For example, first gate oxide layer 218 may be silicon dioxide, silicon oxycarbonitride (SiOCN), silicon oxycarbide (SiOC), or silicon oxynitride (SiON), to name a few examples. First gate oxide layer 218 may have a thickness between about 3 nm and about 5 nm.

Sacrificial gate 220 may extend across the fins in a second direction that is orthogonal to the first direction. According to some embodiments, the sacrificial gate material is formed in parallel strips across the integrated circuit and removed in all areas not protected by a gate masking layer. Sacrificial gate 220 may be any suitable material that can be selectively removed without damaging the semiconductor material of the fins. In some examples, sacrificial gate 220 includes polysilicon.

Following the formation of sacrificial gate 220 (and prior to removal of any part of sacrificial gate 220), additional semiconductor device structures are formed that are not shown in these cross-sections. These additional structures include spacer structures on the sidewalls of sacrificial gate 220 and source and drain regions on either ends of each of the fins. The formation of such structures can be accomplished using any number of processing techniques.

FIG. 2H depicts the cross-section view of the structure shown in FIG. 2G following the removal of sacrificial gate 220 and the removal of first gate oxide layer 218 from around fin 215, according to an embodiment of the present disclosure. Sacrificial gate 220 may be removed using an isotropic etching process. Following the removal of sacrificial gate 220, a mask structure 222 is formed over fin 213 while exposing fin 215. Mask structure 222 may be any suitable hard mask material, such as CHM. The exposed first gate oxide layer 218 around fin 215 may be removed using any suitable isotropic etching process.

FIG. 2I depicts the cross-section view of the structure shown in FIG. 2H following the removal of sacrificial layers 206 from fin 215, according to some embodiments. The removal of sacrificial layers 206 release nanoribbons 224 that extend between corresponding source and drain regions. It should be understood that nanoribbons 224 may also be nanowires or nanosheets (e.g., from a forksheet arrangement).

FIG. 2J depicts the cross-section view of the structure shown in FIG. 2I following the formation of a second gate oxide layer 226 around nanoribbons 224 of the GAA device, according to some embodiments. Second gate oxide layer 226 may be a low-k dielectric material having a dielectric constant between 4 and 6. For example, second gate oxide layer 226 may be silicon dioxide, silicon oxycarbonitride (SiOCN), silicon oxycarbide (SiOC), or silicon oxynitride (SiON), to name a few examples. Second gate oxide layer 226 may have a thickness between about 1 nm and about 3 nm. According to some embodiments, first gate oxide layer 218 is at least 1 nm thicker, at least 2 nm thicker, or at least 5 nm thicker than second gate oxide layer 226. Second gate oxide layer 226 may be deposited using ALD, or any other suitable conformal deposition technique. According to some embodiments, second gate oxide layer 226 also forms over the exposed portion of subfin region 217b beneath nanoribbons 224.

FIG. 2K depicts the cross-section view of the structure shown in FIG. 2J following the formation of gate electrode 228a over fin 213 and gate electrode 228b over nanoribbons 224, according to some embodiments. In some examples, prior to the formation of gate electrode 228a/228b, any number of other dielectric layers may be formed over first gate oxide layer 218 and second gate oxide layer 226. In some embodiments, at least one high-k dielectric layer (e.g., having a dielectric constant greater than 6.5) is formed on both first gate oxide layer 218 and second gate oxide layer 226. Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. According to some embodiments, the at least one high-k dielectric layer includes a layer of hafnium oxide with a thickness between about 1 nm and about 5 nm.

As noted above, gate electrode 228a/228b can represent any number of conductive layers. The conductive gate electrode 228a/228b may be deposited using electroplating, electroless plating, CVD, PECVD, ALD, or PVD, to name a few examples. In some embodiments, gate electrode 228a/228b includes doped polysilicon, a metal, or a metal alloy. Example suitable metals or metal alloys include aluminum, tungsten, cobalt, molybdenum, ruthenium, titanium, tantalum, copper, and carbides and nitrides thereof. Gate electrode 228a/228b may include, for instance, a metal fill material along with one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates. Following the formation of the gate structure, the entire structure may be polished or planarized such that the top surface of the gate structure (e.g., top surface of gate electrode 228a/228b) is coplanar with the top surface of other semiconductor elements, such as the spacer structures that define the gate trench.

As shown in this example, due to the order of the alternating layers within well 202, a top surface of the topmost nanoribbon 224 is substantially coplanar with a top surface of fin 213. If the layer order of the layer structure had been switched (such that a sacrificial layer 206 is at the top), then a top surface of the topmost nanoribbon 224 would be below a top surface of fin 213. In such cases, the difference in height between the top surface of the topmost nanoribbon 224 and the top surface of fin 213 is substantially equal to a thickness of the topmost sacrificial layer 206 formed within well 202.

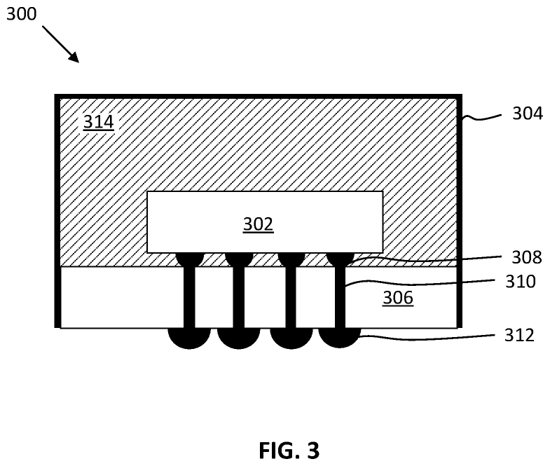

FIG. 3 illustrates an example embodiment of a chip package 300, in accordance with an embodiment of the present disclosure. As can be seen, chip package 300 includes one or more dies 302. One or more dies 302 may include at least one integrated circuit having semiconductor devices, such as any of the semiconductor devices disclosed herein. One or more dies 302 may include any other circuitry used to interface with other devices formed on the dies, or other devices connected to chip package 300, in some example configurations.

As can be further seen, chip package 300 includes a housing 304 that is bonded to a package substrate 306. The housing 304 may be any standard or proprietary housing, and may provide, for example, electromagnetic shielding and environmental protection for the components of chip package 300. The one or more dies 302 may be conductively coupled to a package substrate 306 using connections 308, which may be implemented with any number of standard or proprietary connection mechanisms, such as solder bumps, ball grid array (BGA), pins, or wire bonds, to name a few examples. Package substrate 306 may be any standard or proprietary package substrate, but in some cases includes a dielectric material having conductive pathways (e.g., including conductive vias and lines) extending through the dielectric material between the faces of package substrate 306, or between different locations on each face. In some embodiments, package substrate 306 may have a thickness less than 1 millimeter (e.g., between 0.1 millimeters and 0.5 millimeters), although any number of package geometries can be used. Additional conductive contacts 312 may be disposed at an opposite face of package substrate 306 for conductively contacting, for instance, a printed circuit board (PCB). One or more vias 310 extend through a thickness of package substrate 306 to provide conductive pathways between one or more of connections 308 to one or more of contacts 312. Vias 310 are illustrated as single straight columns through package substrate 306 for ease of illustration, although other configurations can be used (e.g., damascene, dual damascene, through-silicon via, or an interconnect structure that meanders through the thickness of substrate 306 to contact one or more intermediate locations therein). In still other embodiments, vias 310 are fabricated by multiple smaller stacked vias, or are staggered at different locations across package substrate 306. In the illustrated embodiment, contacts 312 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 312, to inhibit shorting.

In some embodiments, a mold material 314 may be disposed around the one or more dies 302 included within housing 304 (e.g., between dies 302 and package substrate 306 as an underfill material, as well as between dies 302 and housing 304 as an overfill material). Although the dimensions and qualities of the mold material 314 can vary from one embodiment to the next, in some embodiments, a thickness of mold material 314 is less than 1 millimeter. Example materials that may be used for mold material 314 include epoxy mold materials, as suitable. In some cases, the mold material 314 is thermally conductive, in addition to being electrically insulating.

### Methodology

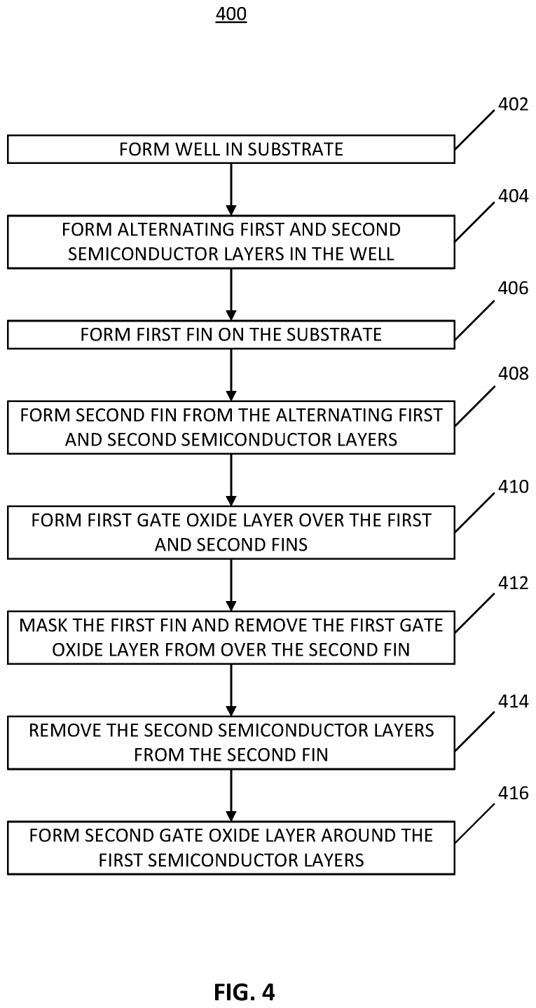

FIG. 4 is a flow chart of a method 400 for forming at least a portion of an integrated circuit, according to an embodiment. Various operations of method 400 may be illustrated in FIGS. 2A-2K. However, the correlation of the various operations of method 400 to the specific components illustrated in the aforementioned figures is not intended to imply any structural and/or use limitations. Rather, the aforementioned figures provide one example embodiment of method 400. Other operations may be performed before, during, or after any of the operations of method 400. For example, method 400 does not explicitly describe all processes that are performed to form common transistor structures. Some of the operations of method 400 may be performed in a different order than the illustrated order.

Method 400 begins with operation 402 where a well is formed in a substrate. The well may be formed using an anisotropic etching process, such as reactive ion etching (RIE). A mask structure may be used to protect other portions of the substrate from the etching process. The well may have any width to accommodate any number of GAA devices within it. The depth of the well may be selected based on a number of desired nanoribbons within the GAA devices and on a desired thickness and spacing between the nanoribbons. According to some embodiments, a dielectric liner may be formed on the sidewalls of the well, such as a layer of silicon nitride.

Method 400 continues with operation 404 where alternating first and second semiconductor layers are formed within the well. Alternating material layers may be formed within the well including sacrificial layers alternating with semiconductor layers. The alternating layers are used to form GAA transistor structures during later operations. Any number of alternating semiconductor layers and sacrificial layers may be formed within the well. In some embodiments, the first semiconductor layers include silicon while the second semiconductor layers (e.g., sacrificial layers) include silicon and germanium.

Method 400 continues with operation 406 where a first fin is formed on the substrate outside of the well. A dielectric cap layer may first be patterned on the substrate to determine the location of the first fin. An RIE process or any other suitable anisotropic etching process can then be carried out to recess the substrate around the dielectric cap layer, thus leaving the first fin beneath the cap layer. According to some embodiments, the first fin includes the same semiconductor material as the substrate.

Method 400 continues with operation 408 where a second fin is formed from the alternating first and second semiconductor layers. A dielectric cap layer may first be patterned over the well to determine the location of the second fin. An RIE process or any other suitable anisotropic etching process can then be carried out to recess the alternating semiconductor layers around the dielectric cap layer, thus leaving the second fin beneath the cap layer. According to some embodiments, the second fin includes the alternating first and second semiconductor layers. Due to the etch rate difference between the first and second semiconductor layers, the RIE process through the well region may etch deeper into the substrate compared to the RIE process through the substrate from operation 406. These processes may occur simultaneously as a single RIE process that etches around the dielectric cap layers.

Method 400 continues with operation 410 where a first gate oxide layer is formed over the first and second fins. The first gate oxide layer may be deposited using CVD or ALD to conformally coat the first and second fins. The first gate oxide layer may be a low-k dielectric material having a dielectric constant between 4 and 6. For example, the first gate oxide layer may be silicon dioxide, silicon oxycarbonitride (SiOCN), silicon oxycarbide (SiOC), or silicon oxynitride (SiON), to name a few examples. The first gate oxide layer may have a thickness between about 3 nm and about 5 nm.

Method 400 continues with operation 412 where the first fin is masked and the first gate oxide layer is removed from around the second fin. According to some embodiments, a hard mask material, such as CHM, is used to protect the first fin while exposing the second fin and the first gate oxide layer around the second fin. Any suitable isotropic etching process may then be used to remove the first gate oxide layer from around the second fin. The removal of the first gate oxide layer exposes the alternating semiconductor layers of the second fin, according to some embodiments.

Method 400 continues with operation 414 where the second semiconductor layers are removed from the second fin. According to some embodiments, a selective isotropic etching process is performed that includes a high etch rate for the second semiconductor layers and a substantially lower etch rate for the first semiconductor layers. Accordingly, the first semiconductor layers remain virtually untouched following the removal of the second semiconductor layers. The first semiconductor layers span across a gate trench as nanoribbons extending from a source region to a drain region.

Method 400 continues with operation 416 where a second gate oxide layer is formed around the first semiconductor layers. The second gate oxide layer may be a low-k dielectric material having a dielectric constant between 4 and 6. For example, the second gate oxide layer may be silicon dioxide, silicon oxycarbonitride (SiOCN), silicon oxycarbide (SiOC), or silicon oxynitride (SiON), to name a few examples. The second gate oxide layer may have a thickness between about 1 nm and about 3 nm. According to some embodiments, the first gate oxide layer is at least 1 nm thicker, at least 2 nm thicker, or at least 5 nm thicker than the second gate oxide layer. The second gate oxide layer may be deposited using ALD, or any other suitable conformal deposition technique. According to some embodiments, the first and second gate oxide layers have the same material composition.

### Example System

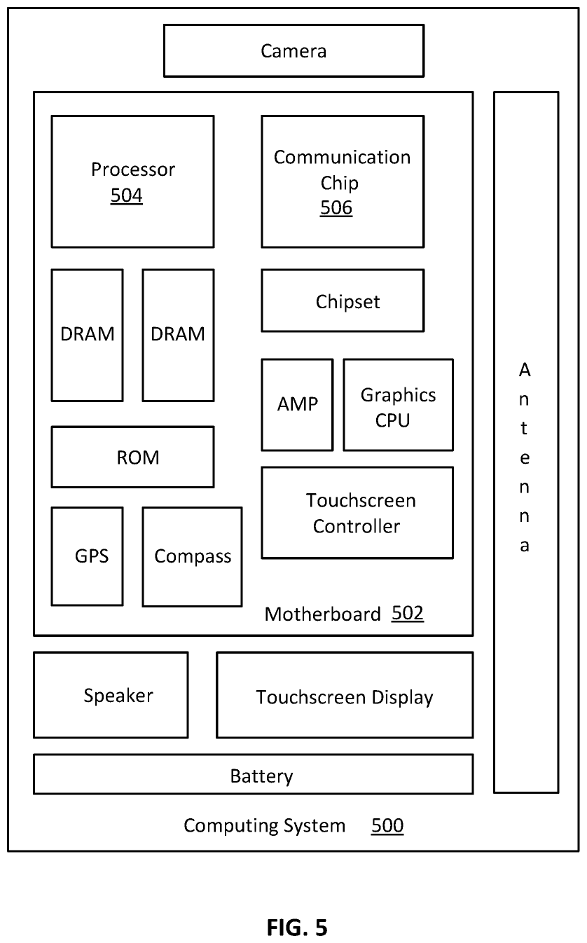

FIG. 5 is an example computing system implemented with one or more of the integrated circuit structures as disclosed herein, in accordance with some embodiments of the present disclosure. As can be seen, the computing system 500 houses a motherboard 502. The motherboard 502 may include a number of components, including, but not limited to, a processor 504 and at least one communication chip 506, each of which can be physically and electrically coupled to the motherboard 502, or otherwise integrated therein. As will be appreciated, the motherboard 502 may be, for example, any printed circuit board (PCB), whether a main board, a daughterboard mounted on a main board, or the only board of system 500, etc.

Depending on its applications, computing system 500 may include one or more other components that may or may not be physically and electrically coupled to the motherboard 502. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 500 may include one or more integrated circuit structures or devices configured in accordance with an example embodiment, such as a module including an integrated circuit on a substrate, the substrate having semiconductor devices and at least one gate cut having a hybrid material structure (e.g., having both low-k and high-k dielectric materials). In some embodiments, multiple functions can be integrated into one or more chips (e.g., for instance, note that the communication chip 506 can be part of or otherwise integrated into the processor 504).

The communication chip 506 enables wireless communications for the transfer of data to and from the computing system 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing system 500 includes an integrated circuit die packaged within the processor 504. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 506 also may include an integrated circuit die packaged within the communication chip 506. In accordance with some such example embodiments, the integrated circuit die of the communication chip includes one or more semiconductor devices as variously described herein. As will be appreciated in light of this disclosure, note that multi-standard wireless capability may be integrated directly into the processor 504 (e.g., where functionality of any chips 506 is integrated into processor 504, rather than having separate communication chips). Further note that processor 504 may be a chip set having such wireless capability. In short, any number of processor 504 and/or communication chips 506 can be used. Likewise, any one chip or chip set can have multiple functions integrated therein.

In various implementations, the computing system 500 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 500 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.
Example 1 is an integrated circuit that includes a first semiconductor device having a semiconductor fin extending in a first direction from a first source region to a first drain region, and a first gate structure extending in a second direction over the semiconductor fin, and a second semiconductor device having a plurality of semiconductor bodies extending in the first direction from a second source region to a second drain region, and a second gate structure extending in the second direction over the plurality of semiconductor bodies. The first gate structure has a first gate dielectric structure and a first gate electrode on the first gate dielectric structure and the second gate structure has a second gate dielectric structure and a second gate electrode on the second gate dielectric structure. The first gate dielectric structure includes a first gate oxide layer and the second gate dielectric structure includes a second gate oxide layer. The first gate oxide layer is at least 2 nm thicker than the second gate oxide layer.
Example 2 includes the integrated circuit of Example 1, wherein the semiconductor fin and the plurality of semiconductor bodies comprise germanium, silicon, or a combination thereof, and the semiconductor bodies are one or more nanoribbons or nanowires.
Example 3 includes the integrated circuit of Example 1 or 2, wherein the first gate dielectric structure includes a first layer of high-k material and the second gate dielectric structure includes a second layer of high-k material.
Example 4 includes the integrated circuit of Example 3, wherein the first layer of high-k material and the second layer of high-k material each have substantially the same thickness.
Example 5 includes the integrated circuit of Example 3 or 4, wherein the first layer of high-k material and the second layer of high-k material each comprise hafnium and oxygen.
Example 6 includes the integrated circuit of any one of Examples 1-5, wherein the first gate oxide layer has a thickness between about 3 nm and about 5 nm.
Example 7 includes the integrated circuit of any one of Examples 1-6, where a topmost surface of the semiconductor fin is substantially coplanar with a topmost surface of a topmost semiconductor body of the plurality of semiconductor bodies.
Example 8 includes the integrated circuit of any one of Examples 1-7, further comprising a first subfin region under the semiconductor fin, a first dielectric layer adjacent to the first subfin region, a second subfin region under the plurality of semiconductor bodies, and a second dielectric layer adjacent to at least a portion of the second subfin region. The second dielectric layer has a greater thickness than the first dielectric layer.
Example 9 includes the integrated circuit of any one of Examples 1-8, further comprising a substrate wherein the semiconductor fin is part of the substrate and the plurality of semiconductor bodies are over the substrate.
Example 10 is a printed circuit board having the integrated circuit of any one of Examples 1-9.
Example 11 is an electronic device that includes a chip package having one or more dies. At least one of the one or more dies includes a substrate, a first semiconductor device on the substrate and having a semiconductor fin extending in a first direction from a first source region to a first drain region, and a first gate structure extending in a second direction over the semiconductor fin, and a second semiconductor device on the substrate and having a plurality of semiconductor nanoribbons extending in the first direction from a second source region to a second drain region, and a second gate structure extending in the second direction over the plurality of semiconductor nanoribbons. The first gate structure has a first gate dielectric structure and a first gate electrode on the first gate dielectric structure and the second gate structure has a second gate dielectric structure and a second gate electrode on the second gate dielectric structure. The first gate dielectric structure includes a first gate oxide layer and the second gate dielectric structure includes a second gate oxide layer. The first gate oxide layer is at least 2 nm thicker than the second gate oxide layer.
Example 12 includes the electronic device of Example 11, wherein the semiconductor fin and the plurality of semiconductor nanoribbons comprise germanium, silicon, or a combination thereof.
Example 13 includes the electronic device of Example 11 or 12, wherein the first gate dielectric structure includes a first layer of high-k material and the second gate dielectric structure includes a second layer of high-k material.
Example 14 includes the electronic device of Example 13, wherein the first layer of high-k material and the second layer of high-k material each have substantially the same thickness.
Example 15 includes the electronic device of Example 13 or 14, wherein the first layer of high-k material and the second layer of high-k material each comprise hafnium and oxygen.
Example 16 includes the electronic device of any one of Examples 11-15, wherein the first gate oxide layer has a thickness between about 3 nm and about 5 nm.
Example 17 includes the electronic device of any one of Examples 11-16, where a top surface of the semiconductor fin is substantially coplanar with a top surface of a topmost nanoribbon of the plurality of semiconductor nanoribbons.
Example 18 includes the electronic device of any one of Examples 11-17, wherein the semiconductor fin includes a first subfin region having a first dielectric layer adjacent to the first subfin region and the plurality of semiconductor nanoribbons includes a second subfin region having a second dielectric layer adjacent to at least a portion of the second subfin region, the second dielectric layer having a greater thickness than the first dielectric layer.
Example 19 includes the electronic device of any one of Examples 11-18, wherein the semiconductor fin is part of the substrate and the plurality of semiconductor nanoribbons are over the substrate.
Example 20 includes the electronic device of any one of Examples 11-19, further comprising a printed circuit board, wherein the chip package is coupled to the printed circuit board.
Example 21 is a method of forming an integrated circuit. The method includes forming a recess in a substrate; forming alternating first and second semiconductor layers within the recess; forming a first fin comprising first semiconductor material, the first fin extending above the substrate and extending in a first direction; forming a second fin comprising the first and second semiconductor layers, the second fin extending above the substrate and extending in the first direction; forming a first gate oxide layer having a first thickness over the first fin and the second fin; forming a masking layer over the first fin and removing the first gate oxide layer from the second fin; removing the second semiconductor layers from the second fin to yield semiconductor nanoribbons from the first semiconductor layers; and forming a second gate oxide layer having a second thickness around the semiconductor nanoribbons, wherein the second thickness of the second gate oxide layer is less than the first thickness of the first gate oxide layer.
Example 22 includes the method of Example 21, wherein the second thickness is less than the first thickness by at least 2 nm.
Example 23 includes the method of Example 21 or 22, further comprising removing the masking layer; forming a first gate electrode over the first gate oxide layer; and forming a second gate electrode over the second gate oxide layer.
Example 24 includes the method of Example 21 or 22, further comprising removing the masking layer; and forming a layer of high-k material on both the first gate oxide layer and the second gate oxide layer.
Example 25 includes the method of Example 24, wherein the layer of high-k material comprises hafnium and oxygen.
Example 26 includes the method of any one of Examples 21-25, wherein the first gate oxide layer has a thickness between about 3 nm and about 5 nm.
Example 27 is an integrated circuit that includes a substrate including a first subfin region and a second subfin region, a first semiconductor device having a semiconductor fin above the first subfin region and extending in a first direction between a first source region and a first drain region, and a first gate structure extending in a second direction over the semiconductor fin, a second semiconductor device having a plurality of semiconductor nanoribbons above the second subfin region and extending in the first direction between a second source region and a second drain region, and a second gate structure extending in the second direction over the plurality of semiconductor nanoribbons, a first dielectric layer adjacent to the first subfin region, and a second dielectric layer adjacent to at least a portion of the second subfin region. The first gate structure has a first gate dielectric structure and a first gate electrode on the first gate dielectric structure. The second gate structure has a second gate dielectric structure and a second gate electrode on the second gate dielectric structure. The second dielectric layer has a greater thickness than the first dielectric layer.
Example 28 includes the integrated circuit of Example 27, wherein the semiconductor fin is part of the substrate, and the semiconductor fin and plurality of semiconductor nanoribbons comprise germanium, silicon, or a combination thereof.
Example 29 includes the integrated circuit of Example 27 or 28, wherein the first gate dielectric structure includes a first layer of high-k material and the second gate dielectric structure includes a second layer of high-k material.
Example 30 includes the integrated circuit of Example 29, wherein the first layer of high-k material and the second layer of high-k material each have substantially the same thickness.
Example 31 includes the integrated circuit of Example 29 or 30, wherein the first layer of high-k material and the second layer of high-k material each comprise hafnium and oxygen.
Example 32 includes the integrated circuit of any one of Examples 27-31, wherein the first gate dielectric structure includes a first gate oxide layer having a thickness between about 3 nm and about 5 nm.
Example 33 includes the integrated circuit of any one of Examples 27-32, where a top surface of the semiconductor fin is substantially coplanar with a top surface of a topmost nanoribbon of the plurality of semiconductor nanoribbons.
Example 34 includes the integrated circuit of any one of Examples 27-33, wherein the first gate dielectric structure includes a first gate oxide layer and the second gate dielectric structure includes a second gate oxide layer, wherein the first gate oxide layer is at least 2 nm thicker than the second gate oxide layer.
Example 35 is a printed circuit board that includes the integrated circuit of any one of Examples 27-34.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first semiconductor device having a semiconductor fin extending in a first direction from a first source region to a first drain region, and a first gate structure extending in a second direction over the semiconductor fin, the first gate structure having a first gate dielectric structure and a first gate electrode on the first gate dielectric structure; and
a second semiconductor device having a plurality of semiconductor bodies extending in the first direction from a second source region to a second drain region, and a second gate structure extending in the second direction over the plurality of semiconductor bodies, the second gate structure having a second gate dielectric structure and a second gate electrode on the second gate dielectric structure;
wherein the first gate dielectric structure includes a first gate oxide layer and the second gate dielectric structure includes a second gate oxide layer, wherein the first gate oxide layer is at least 2 nm thicker than the second gate oxide layer.

2. The integrated circuit of claim 1, wherein the first gate dielectric structure includes a first layer of high-k material and the second gate dielectric structure includes a second layer of high-k material.

3. The integrated circuit of claim 2, wherein the first layer of high-k material and the second layer of high-k material each have substantially the same thickness.

4. The integrated circuit of claim 2, wherein the first layer of high-k material and the second layer of high-k material each comprise hafnium and oxygen.

5. The integrated circuit of claim 1, where a topmost surface of the semiconductor fin is substantially coplanar with a topmost surface of a topmost semiconductor body of the plurality of semiconductor bodies.

6. The integrated circuit of claim 1, comprising:
a first subfin region under the semiconductor fin;
a first dielectric layer adjacent to the first subfin region;
a second subfin region under the plurality of semiconductor bodies; and
a second dielectric layer adjacent to at least a portion of the second subfin region, the second dielectric layer having a greater thickness than the first dielectric layer.

7. The integrated circuit of claim 1, further comprising a substrate wherein the semiconductor fin is part of the substrate and the plurality of semiconductor bodies are over the substrate.

8. A printed circuit board comprising the integrated circuit of claim 1.

9. An electronic device, comprising:
a chip package comprising one or more dies, at least one of the one or more dies comprising
a substrate;
a first semiconductor device on the substrate and having a semiconductor fin extending in a first direction between a first source region and a first drain region, and a first gate structure extending in a second direction over the semiconductor fin, the first gate structure having a first gate dielectric structure and a first gate electrode on the first gate dielectric structure; and
a second semiconductor device on the substrate and having a plurality of semiconductor nanoribbons extending in the first direction between a second source region and a second drain region, and a second gate structure extending in the second direction over the plurality of semiconductor nanoribbons, the second gate structure having a second gate dielectric structure and a second gate electrode on the second gate dielectric structure;
wherein the first gate dielectric structure includes a first gate oxide layer and the second gate dielectric structure includes a second gate oxide layer, wherein the first gate oxide layer is at least 2 nm thicker than the second gate oxide layer.

10. The electronic device of claim 9, wherein the first gate dielectric structure includes a first layer of high-k material and the second gate dielectric structure includes a second layer of high-k material.

11. The electronic device of claim 10, wherein the first layer of high-k material and the second layer of high-k material each comprise hafnium and oxygen.

12. The electronic device of claim 9, where a top surface of the semiconductor fin is substantially coplanar with a top surface of a topmost nanoribbon of the plurality of semiconductor nanoribbons.

13. The electronic device of claim 9, wherein the semiconductor fin includes a first subfin region having a first dielectric layer adjacent to the first subfin region and the plurality of semiconductor nanoribbons includes a second subfin region having a second dielectric layer adjacent to at least a portion of the second subfin region, the second dielectric layer having a greater thickness than the first dielectric layer.

14. The electronic device of claim 9, wherein the semiconductor fin is part of the substrate and the plurality of semiconductor nanoribbons are over the substrate.

15. An integrated circuit comprising:
a substrate including a first subfin region and a second subfin region;
a first semiconductor device having a semiconductor fin above the first subfin region and extending in a first direction between a first source region and a first drain region, and a first gate structure extending in a second direction over the semiconductor fin, the first gate structure having a first gate dielectric structure and a first gate electrode on the first gate dielectric structure;
a second semiconductor device having a plurality of semiconductor nanoribbons above the second subfin region and extending in the first direction between a second source region and a second drain region, and a second gate structure extending in the second direction over the plurality of semiconductor nanoribbons, the second gate structure having a second gate dielectric structure and a second gate electrode on the second gate dielectric structure;
a first dielectric layer adjacent to the first subfin region, and
a second dielectric layer adjacent to at least a portion of the second subfin region, the second dielectric layer having a greater thickness than the first dielectric layer.

16. The integrated circuit of claim 15, wherein the first gate dielectric structure includes a first layer of high-k material and the second gate dielectric structure includes a second layer of high-k material.

17. The integrated circuit of claim 16, wherein the first layer of high-k material and the second layer of high-k material each have substantially the same thickness.

18. The integrated circuit of claim 16, wherein the first layer of high-k material and the second layer of high-k material each comprise hafnium and oxygen.

19. The integrated circuit of claim 15, where a top surface of the semiconductor fin is substantially coplanar with a top surface of a topmost nanoribbon of the plurality of semiconductor nanoribbons.

20. The integrated circuit of claim 15, wherein the first gate dielectric structure includes a first gate oxide layer and the second gate dielectric structure includes a second gate oxide layer, wherein the first gate oxide layer is at least 2 nm thicker than the second gate oxide layer.
